(19) United States
(12) Patent Application Publication
(10) Pub. No.: US 2026/0185208 A1
(43) Pub. Date: Jul. 2, 2026

(54) TRANSPARENT CONDUCTIVE METAL OXIDE COATING FOR PHOTOVOLTAIC CELLS, DISPLAYS, AND TOUCH SCREEN DEVICES

(71) Applicant: Peter East, Gold Canyon, AZ (US)

(72) Inventor: Peter East, Gold Canyon, AZ (US)

(21) Appl. No.: 19/435,926

(22) Filed: Dec. 30, 2025

Related U.S. Application Data
(60) Provisional application No. 63/740,207, filed on Dec. 30, 2024.

(51) Int. Cl. C23C 14/08; C23C 14/18; H10F 71/00; H10F 77/20

(52) U.S. Cl. CPC C23C 14/08; C23C 14/18; H10F 71/128; H10F 77/211

(57) ABSTRACT

Fabricating a device includes vacuum depositing a metal layer over a silicon substrate, and vacuum depositing a metal oxide layer on the metal layer, thereby disposing the metal layer between a surface of the silicon substrate and the metal oxide layer. In one example, the device is a photovoltaic device or part of a display or touch screen device.

### CROSS-REFERENCE TO RELATED APPLICATION

This application claims the benefit of U.S. Patent Application No. 63/740,207 filed on Dec. 30, 2024, which is incorporated by reference herein in its entirety.

### TECHNICAL FIELD

This invention relates to modification of the top and bottom surfaces of a photovoltaic cell to improve electrical performance.

### BACKGROUND

Metal oxides are used during photovoltaic cell fabrication on the front (sun-facing) surface of the cell and rear contact to provide a current path for operation.

### SUMMARY

This disclosure describes the addition of a metal layer disposed between metal oxide layers (e.g., transparent conductive oxide layers) on one or more sides of a silicon substrate in a photovoltaic cell. The thicknesses of the metal layer and the metal oxide layers can be tuned to reflect longer wavelengths, reduce photovoltaic cell operating temperatures, and protect from radiation damage to further enhance device performance. This allows reduction or elimination of fingered electrode structures on the face of the photovoltaic cell, which can create fixed shadow regions and reduce electrical efficiency.

In a first general aspect, fabricating a device includes vacuum depositing a metal layer over a silicon substrate, and vacuum depositing a metal oxide layer on the metal layer, thereby disposing the metal layer between a surface of the silicon substrate and the metal oxide layer.

Implementations of the first general aspect may include one or more of the following features.

In some implementations, the device is a photovoltaic device (e.g., a photovoltaic cell) or part of a display or touch screen device. In some cases, the metal layer is deposited directly on (e.g., in direct contact with) the surface of the silicon substrate. In certain cases, there is an intervening layer (e.g., a metal oxide layer) between the surface of the silicon substrate and the metal layer. The intervening layer can be in direct contact with the surface of the silicon substrate.

A thickness of the metal layer is typically in a range of 6 nm to 40 nm. The metal layer can be composed of silver, aluminum, copper, gold, or a combination thereof. A thickness of the metal oxide layer is typically in a range of 10 nm to 50 nm. The metal oxide layer can be composed of aluminum zinc oxide, indium zinc oxide, indium tin oxide, tin oxide, zinc oxide, cerium oxide, gallium zinc oxide, hydrogenated indium oxide, indium cerium oxide, or a combination thereof.

The silicon substrate can include a layer of crystalline n-type silicon having a first surface and a second surface opposite the first surface. The first surface, the second surface, or both can be textured (e.g. intentionally textured to achieve a desired pattern or roughness). The first surface and the second surface can be in contact with a first layer of intrinsic amorphous silicon and a second layer of intrinsic amorphous silicon, respectively. The first layer of intrinsic amorphous silicon and the second layer of intrinsic amorphous silicon are in contact with a first layer of doped amorphous silicon and a second layer of doped amorphous silicon, respectively.

Vacuum depositing the metal oxide layer can include forming the metal oxide layer on the metal layer in a vacuum chamber using a radiofrequency or direct current discharge. The radiofrequency or direct current discharge can include argon and oxygen gas. A pressure in the vacuum chamber is typically in a range of 1 mTorr to 25 mTorr.

Some implementations of the first general aspect can include annealing the device in air at a temperature in a range of 200° C. to 280° C. Implementations of the first general aspect can include disposing an electrically conductive material on the metal oxide layer, thereby forming a metal contact on the metal oxide layer.

Some implementations of the first general aspect can include, before vacuum depositing the metal layer, vacuum depositing an additional metal oxide layer on the silicon substrate, thereby disposing the metal layer between the metal oxide layer and the additional metal oxide layer. The metal layer cam be in direct contact with the metal oxide layer and the additional metal oxide layer.

Some implementations of the first general aspect can include vacuum depositing an additional metal oxide layer on an additional surface of the silicon substrate, wherein the additional surface of the silicon substrate is opposite the surface of the silicon substrate, and can optionally include i) vacuum depositing an additional metal layer on the additional metal oxide layer, ii) vacuum depositing a second additional metal oxide layer on the additional metal layer, thereby disposing the additional metal layer between the additional metal oxide layer and the second additional metal oxide layer, or i) and ii). A thickness of the additional metal oxide layer is typically in a range of 25 nm to 200 nm. A thickness of the additional metal layer is typically in a range up to 200 nm. A thickness of the second additional metal oxide layer is typically in a range up to 50 nm. Some implementations of the first general aspect can further include vacuum depositing a metal electrode layer on the second additional metal oxide layer to yield the device. A thickness of the metal electrode layer is typically in a range of 100 nm to 300 nm.

Some implementations include vacuum depositing an additional metal layer on the metal oxide layer, and vacuum depositing an additional metal oxide layer on the additional metal layer.

A second general aspect includes a device fabricated by the method of the first general aspect. The device can be a photovoltaic device (e.g., a photovoltaic cell) or part of a display or touch screen device.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 shows a cross-sectional schematic diagram of an example encapsulated metal layer.

FIG. 2 shows a cross-sectional schematic diagram of an example photovoltaic cell.

FIG. 3 shows a cross-sectional schematic diagram of an example photovoltaic cell.

FIG. 4 shows a cross-sectional schematic diagram of an example photovoltaic cell.

### DETAILED DESCRIPTION

This disclosure describes methods of fabricating devices (e.g., photovoltaic devices or a part of a display or touch screen device) as well as the resulting devices. In methods described herein, an encapsulated metal layer is formed on the front side, the rear side, or both sides of a silicon substrate of a photovoltaic device (e.g., the sun-facing side and/or the rear side). The encapsulated metal layer includes a metal layer disposed between two metal oxide layers. The metal layer can be in direct contact with one or both of the metal oxide layers. In some implementations, an encapsulated metal layer includes a metal layer disposed between two layers, one of which is a metal oxide layer. Suitable examples of metals for the metal layers include silver, aluminum, copper, gold, or a combination thereof. Suitable examples of metal oxides for the metal oxide layers include aluminum zinc oxide, indium zinc oxide, indium tin oxide, tin oxide, zinc oxide, cerium oxide, gallium zinc oxide, hydrogenated indium oxide, indium cerium oxide, or a combination thereof. For photovoltaic devices with more than one metal layer, the metal in the metal layers can be the same or different. For photovoltaic devices with more than one metal oxide layer, the metal oxide in the metal oxide layers can be the same or different

The use of a metal layer in a photovoltaic device can provide protection against damage mechanisms encountered in various environments (e.g., space). For example, the metal layer can protect a photovoltaic device from ultraviolet photodegradation, atomic oxygen erosion, surface charging, electrostatic discharge, low-energy sputtering, environmental surface defect formation, and metal oxide degradation from bombardment of high-energy protons, electrons, or cosmic rays.

The metal oxide layers are optically transparent and electrically conductive. Optically transparent metal oxide layers allow the transmission of incident light within the wavelength range of 350 nm to 1100 nm (e.g., at least 80%, 90%, 95%, or 99% transmittance) to the underlying layers of a photovoltaic device. The metal oxide layers provide front optical coupling and carrier collection in a photovoltaic device. The metal oxide layers are radiation-resistant and help prevent degradation, thereby preserving optical throughput.

In a photovoltaic device with a silicon substrate, the encapsulated metal layer is anti-reflective and radiation-blocking. The encapsulated metal layer on the sun-facing side of the device filters high-energy radiation, thereby improving shielding effects. The material selection and thickness of the encapsulated metal layer can be tuned to reject certain wavelengths of light (e.g., infrared or ultraviolet).

Forming the encapsulated metal layer on the silicon substrate includes placing the silicon substrate in a high vacuum deposition chamber with both metal oxide and metal source materials available. Thin film coatings of metal oxide and metal are disposed on the silicon substrate sequentially (e.g., with no vacuum breaks to the atmosphere). The chamber is evacuated to a pressure of 2×10⁻⁶ Torr or lower before deposition. The total process pressure is in a range from 1 mTorr to 25 mTorr during the deposition.

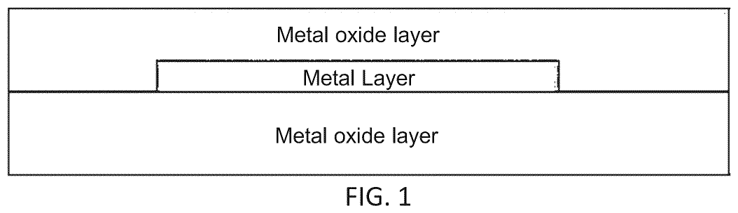

During the deposition of an encapsulated metal layer on a first side (e.g., front side) of the substrate, the second (e.g., opposite or rear side) side of the substrate is protected from wraparound deposition. In some cases, a shadow mask is used to selectively deposit metal on a portion of the metal oxide layer. FIG. 1 is a schematic diagram of an encapsulated metal layer deposited using a shadow mask. In some cases, blanket deposition is used to deposit metal on the metal oxide layer. Blanket deposition refers to the uniform deposition of a material across the entire surface.

Forming a first metal oxide layer on a first side (e.g., a first surface) of the substrate includes vacuum depositing a metal oxide layer to a selected film thickness on the first side of the substrate. The deposition uses a radiofrequency (RF) or direct current (DC) discharge of argon and oxygen gas. The oxygen partial pressure relative to argon is selected to define the desired optical and electrical properties of this layer. A thickness of the metal oxide layer is in a range of 0 nm to 50 nm. That is, in some cases, the first metal oxide layer is optional.

Forming a metal layer includes vacuum depositing a metal layer (e.g., a silver layer) on the first metal oxide layer to a selected film thickness. The vacuum deposition typically uses a DC discharge of argon gas to maximize the conductivity of the metal layer. A thickness of the metal layer is in a range of 6 nm to 40 nm (e.g., 10 nm to 30 nm).

Forming a second metal oxide layer includes vacuum depositing a second metal oxide layer on the metal layer to a selected film thickness. The deposition uses a RF or DC current discharge of argon and oxygen gas. The oxygen partial pressure relative to argon is selected to define the desired optical and electrical properties of this layer individually. A thickness of the second metal oxide layer is in a range of 10 nm to 50 nm.

The substrate can be oriented to deposit an encapsulated metal layer on a second side (or surface) of the substrate. The second side (or surface) of the substrate (e.g., the rear side) is opposite the first side (or surface) of the substrate (e.g., the sun-facing or front side). Forming a first metal oxide layer on the second side of the substrate includes vacuum depositing a first metal oxide layer to a selected film thickness on the second surface of the substrate. The deposition typically uses a RF or DC discharge of argon and oxygen gas. The oxygen partial pressure relative to argon is selected to define the desired optical and electrical properties of this layer individually. A thickness of the first metal oxide layer on the second side of the substrate is in a range of 25 nm to 200 nm.

Some implementations include forming a metal layer on the first metal oxide layer of the second side. Forming the metal layer includes vacuum depositing a metal layer (e.g., a silver layer) on the first metal oxide layer to a selected film thickness. The deposition uses a DC discharge of argon gas to maximize the conductivity of this layer. A thickness of the metal layer can be up to 200 nm.

Some implementations include forming a second metal oxide layer on the metal layer of the second side of the substrate. Forming the second metal oxide layer includes vacuum depositing a metal oxide layer on the metal layer on the second side of the substrate to a selected film thickness. The deposition typically uses a RF or DC discharge of argon and oxygen gas. The oxygen partial pressure relative to argon is selected to define the desired optical and electrical properties of this layer individually. A thickness of the second metal oxide layer on the second side of the substrate can be up to 50 nm.

Forming a metal electrode layer on the second side of the substrate (e.g., on the first metal oxide layer or on the second metal oxide layer) includes vacuum depositing a metal layer (e.g., a silver or aluminum layer) to a selected film thickness. The deposition typically uses a DC discharge including argon gas to maximize the conductivity of this layer. A thickness of the metal electrode layer is in a range of 100 nm to 300 nm (e.g., 150 nm to 250 nm).

After the deposition of layers on the surface(s) of the substrate, the photovoltaic device is annealed in air at a temperature in a range of about 200° C. to about 280° C. (e.g., 200 C, 250° C., or 275° C.). In some cases, annealing is performed in a sequence at varying temperatures. In some examples, annealing is performed in air at a temperature of about 250° C. The metal electrode layer of the second side can be annealed in air at a temperature in a range of 200° C. to 275° C.

After all of the layers are annealed, a metal contact is disposed on the first side of the substrate (e.g., on the second metal oxide layer) using an electrically conductive material (e.g., a silver-based epoxy). The metal contact is typically annealed at a temperature in a range of 100° C. and 250° C. (e.g., 100° C. or 200° C.).

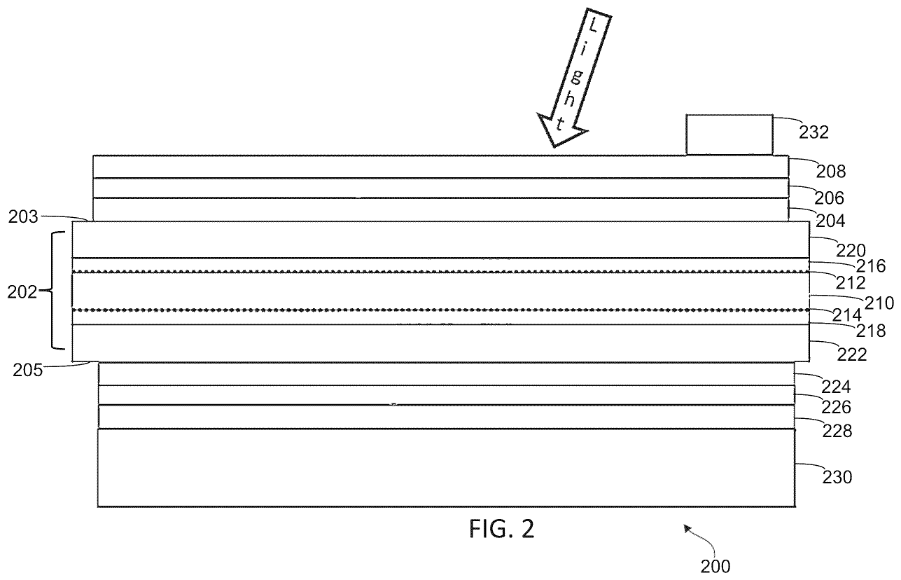

FIG. 2 is a cross-sectional view of an example photovoltaic device 200. The photovoltaic device 200 includes a silicon substrate 202, a first metal oxide layer 204 on a first surface 203 of the silicon substrate 202, a metal layer 206 on the first metal oxide layer 204, and a second metal oxide layer 208 on the metal layer 206. The metal layer 206 is disposed between the first metal oxide layer 204 and second metal oxide layer 208.

The silicon substrate 202 includes a layer of crystalline n-type silicon 210 having a first surface 212 and a second surface 214 opposite a first surface 212. A thickness of the layer of crystalline n-type silicon 210 is in a range of 25 μm to 200 μm (e.g., 150 μm). The first surface 212 and the second surface 214 are textured. The crystalline n-type silicon 210 includes random pyramid texturing. An average width of the pyramid bases is in a range of 0.5 μm to 2 μm (e.g., 1 μm, or 2 μm). An average height of the pyramids, defined as an average of the perpendicular distance from the apex of the pyramid to the base plane, can be up to 1 μm (e.g., 0.7 μm or 0.8 μm). In some cases, the first surface 212 is not textured. In some implementations, the second surface 214 is not textured. In other cases, the first surface 212 and the second surface 214 are not textured. Textured surfaces improve optical absorption of the photovoltaic device 200.

The first surface 212 and the second surface 214 of the crystalline n-type silicon 210 are in contact with a first layer of intrinsic amorphous silicon 216 and a second layer of intrinsic amorphous silicon 218, respectively. A thickness of the first layer of intrinsic amorphous silicon 216 is in a range of 5 nm to 25 nm (e.g., a thickness of 11 nm). A thickness of the second layer of intrinsic amorphous silicon 218 is in a range of 5 nm to 25 nm (e.g., a thickness of 11 nm). The first layer of intrinsic amorphous silicon 216 and the second layer of intrinsic amorphous silicon 218 are in contact with a first layer of doped amorphous silicon 220 and a second layer of doped amorphous silicon 222, respectively. The first layer of doped amorphous silicon 220 is a p-type silicon layer. In some cases, the first layer of doped amorphous silicon 220 includes boron as a dopant. The second layer of doped amorphous silicon 222 is an n-type silicon layer. In some cases, the second layer of doped amorphous silicon 222 includes phosphorous as a dopant. In some cases, the first layer of doped amorphous silicon 220 is an n-type silicon layer. In some implementations, the second layer of doped amorphous silicon 222 is a p-type silicon layer. A thickness of the first layer of doped amorphous silicon 220 is in a range of 5 nm to 30 nm (e.g., a thickness of 15 nm). A thickness of the second layer of doped amorphous silicon 222 is in a range of 5 nm to 30 nm (e.g., a thickness of 15 nm).

The first metal oxide layer 204 is a transparent conductive metal oxide layer. A thickness of the first metal oxide layer 204 is in a range of 0.1 nm to 50 nm. The metal layer 206 can include or be composed of silver. A thickness of the metal layer 206 is in a range of 6 nm to 40 nm (e.g., 10 nm to 30 nm). The second metal oxide layer 208 is a transparent conductive metal oxide layer. The first metal oxide layer 204 and the second metal oxide layer 208 may be the same or different. A thickness of the second metal oxide layer 208 is in a range of 10 nm to 50 nm. Examples of suitable metal oxides for the first and second metal oxide layers include aluminum zinc oxide, indium zinc oxide, indium tin oxide, tin oxide, zinc oxide, cerium oxide, gallium zinc oxide, hydrogenated indium oxide, and indium cerium oxide.

The photovoltaic device 200 can include an encapsulated metal layer on the second surface 205 of the silicon substrate 202. As depicted in FIG. 2, the encapsulated metal layer on the second surface 205 of the silicon substrate 202 includes a first metal oxide layer 224 on a second surface 205 of the silicon substrate 202, a metal layer 226 on the first metal oxide layer 224, and a second metal oxide layer 228 on the metal layer 226. The second surface 205 of the silicon substrate 202 is opposite the first surface 203 of the silicon substrate 202. The metal layer 226 is disposed between the first metal oxide layer 224 and the second metal oxide layer 228.

The first metal oxide layer 224 is a transparent conductive metal oxide layer. A thickness of the first metal oxide layer 224 is typically in a range of 25 nm to 200 nm. The metal layer 226 can be silver. A thickness of the metal layer 226 can be up to 200 nm. The metal layer 226 may be the same as or different from the metal layer 206. The second metal oxide layer 228 is a transparent conductive oxide layer. A thickness of the second metal oxide layer 228 can be up to 50 nm. Examples of suitable metal oxides for the first and second metal oxide layers include aluminum zinc oxide, indium zinc oxide, indium tin oxide, tin oxide, zinc oxide, cerium oxide, gallium zinc oxide, hydrogenated indium oxide, and indium cerium oxide. The first metal oxide layer 224 and the second metal oxide layer 228 may be the same or different. The first metal oxide layer 204, the second metal oxide layer 208, the first metal oxide layer 224, and the second metal oxide layer 228 may be the same or different.

The photovoltaic device 200 includes a metal electrode layer 230 on the second metal oxide layer 228. The metal electrode layer 230 includes silver or aluminum. A thickness of the metal electrode layer 230 is in a range of 100 nm to 300 nm (e.g., 150 nm to 250 nm). An outer surface of the photovoltaic device 200 includes a metal contact 232. In one example, the metal contact 232 is composed of silver.

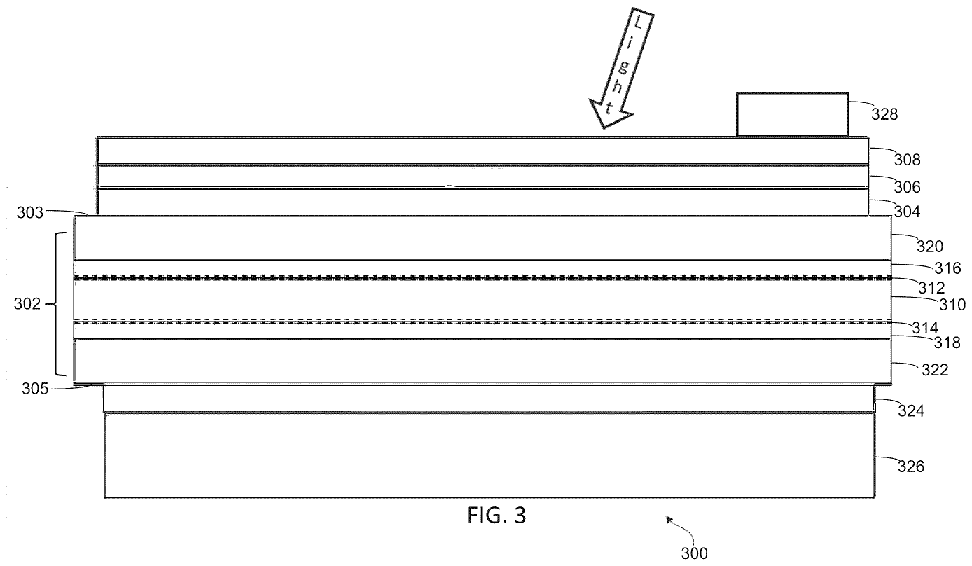

FIG. 3 is a cross-sectional view of an example photovoltaic device 300. The photovoltaic device 300 includes a silicon substrate 302, a first metal oxide layer 304 on a first surface 303 of the silicon substrate 302, a metal layer 306 on the first metal oxide layer 304, and a second metal oxide layer 308 on the metal layer 306. The metal layer 306 is disposed between the first metal oxide layer 304 and the second metal oxide layer 308.

The silicon substrate 302 includes a layer of crystalline n-type silicon 310 having a first surface 312 and a second surface 314 opposite the first surface 312. A thickness of the layer of crystalline n-type silicon 310 is in a range of 25 μm to 200 μm (e.g., 150 μm). The first surface and 312 the second surface 314 are textured. The crystalline n-type silicon 310 includes random pyramid texturing. An average width of the pyramid bases is in a range of 0.5 μm to 2 μm (e.g., 1 μm to 1.5 μm). An average height of the pyramids, defined as an average of the perpendicular distance from the apex of the pyramid to the base plane, can be up to 1 μm (e.g., up to 0.7 μm or up to 0.8 μm). In some cases, the first surface 312 is not textured. In some implementations, the second surface 314 is not textured. In other cases, the first surface 312 and the second surface 314 are not textured.

The first surface 312 and the second surface 314 of the crystalline n-type silicon 310 are in contact with a first layer of intrinsic amorphous silicon 316 and a second layer of intrinsic amorphous silicon 318, respectively. A thickness of the first layer of intrinsic amorphous silicon 316 is typically in a range of 5 nm to 25 nm (e.g., a thickness of 11 nm). A thickness of the second layer of intrinsic amorphous silicon 318 is in a range of 5 nm to 25 nm (e.g., a thickness of 11 nm). The first layer of intrinsic amorphous silicon 316 and the second layer of intrinsic amorphous silicon 318 are in contact with a first layer of doped amorphous silicon 320 and a second layer of doped amorphous silicon 322, respectively. The first layer of doped amorphous silicon 320 is a p-type silicon layer. In some cases, the first layer of doped amorphous silicon 320 includes boron as a dopant. The second layer of doped amorphous silicon 322 is an n-type silicon layer. In some cases, the second layer of doped amorphous silicon 322 includes phosphorous as a dopant. In some cases, the first layer of doped amorphous silicon 320 is an n-type silicon layer. In some implementations, the second layer of doped amorphous silicon 322 is a p-type silicon layer. A thickness of the first layer of doped amorphous silicon 320 is in a range of 5 nm to 30 nm (e.g., a thickness of 15 nm). A thickness of the second layer of doped amorphous silicon 322 is in a range of 5 nm to 30 nm (e.g., a thickness of 15 nm).

The first metal oxide layer 304 is a transparent conductive metal oxide layer. A thickness of the first metal oxide layer 304 is in a range of 0.1 nm to 50 nm. The metal layer 306 can include silver. A thickness of the metal layer 306 is in a range of 6 nm to 40 nm (e.g., 10 nm to 30 nm). The second metal oxide layer 308 is a transparent conductive metal oxide layer. The first metal oxide layer 304 and the second metal oxide layer 308 may be the same or different. A thickness of the second metal oxide layer 308 is in a range of 10 nm to 50 nm. Examples of suitable metal oxides for the first and second metal oxide layers include aluminum zinc oxide, indium zinc oxide, indium tin oxide, tin oxide, zinc oxide, cerium oxide, gallium zinc oxide, hydrogenated indium oxide, and indium cerium oxide.

The photovoltaic device 300 includes a first metal oxide layer 324 on a second surface 305 of the silicon substrate 302. As depicted in FIG. 3, the second surface 305 of the silicon substrate 302 is opposite the first surface 303 of the silicon substrate 302. The first metal oxide layer 324 is a transparent conductive metal oxide layer. A thickness of the first metal oxide layer 324 is in a range of 25 nm to 200 nm. Examples of suitable metal oxides for the first metal oxide layer 324 include aluminum zinc oxide, indium zinc oxide, indium tin oxide, tin oxide, zinc oxide, cerium oxide, gallium zinc oxide, hydrogenated indium oxide, and indium cerium oxide. The first metal oxide layer 304, the second metal oxide layer 308, and the first metal oxide layer 324 may be the same or different.

The photovoltaic device 300 includes a metal electrode layer 326 on the first metal oxide layer 324. The metal electrode layer 326 includes silver or aluminum. A thickness of the metal electrode layer 326 is in a range of 100 nm to 300 nm (e.g., 150 nm to 200 nm). An outer surface of the photovoltaic device 300 includes a metal contact 328. In one example, the metal contact 328 is composed of silver.

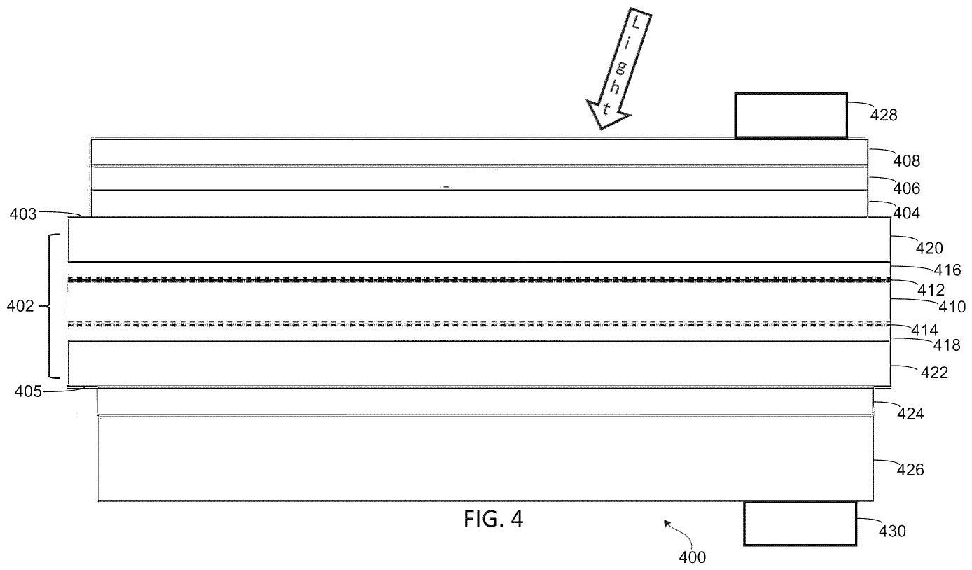

FIG. 4 is a cross-sectional view of an example photovoltaic device 400. The photovoltaic device 400 includes a silicon substrate 402, a first metal oxide layer 404 on a first surface 403 of the silicon substrate 402, a metal layer 406 on the first metal oxide layer 404, and a second metal oxide layer 408 on the metal layer 406. The metal layer 406 is disposed between the first metal oxide layer 404 and the second metal oxide layer 408. The first surface 403 of the silicon substrate 402 is the sun-facing side of the photovoltaic device 400.

The silicon substrate 402 includes a layer of crystalline n-type silicon 410 having a first surface 412 and a second surface 414 opposite the first surface. A thickness of the layer of crystalline n-type silicon 410 is in a range of 25 μm to 200 μm (e.g., 50 μm to 150 μm). The first surface and 412 the second surface 414 are textured. The crystalline n-type silicon 410 includes random pyramid texturing. An average width of the pyramid bases is in a range of 0.5 μm to 2 μm (e.g., 1 μm to 2 μm). An average height of the pyramids, defined as an average of the perpendicular distance from the apex of the pyramid to the base plane, can be up to 1 μm (e.g., 0.7 μm or 0.8 μm). In some cases, the first surface 412 is not textured. In some implementations, the second surface 414 is not textured. In other cases, the first surface 412 and the second surface 414 are not textured.

The first surface 412 and the second surface 414 of the crystalline n-type silicon 410 are in contact with a first layer of intrinsic amorphous silicon 416 and a second layer of intrinsic amorphous silicon 418, respectively. A thickness of the first layer of intrinsic amorphous silicon 416 is in a range of 5 nm to 25 nm (e.g., 10 nm to 20 nm). A thickness of the second layer of intrinsic amorphous silicon 418 is in a range of 5 nm to 25 nm (e.g., 10 nm to 20 nm). The first layer of intrinsic amorphous silicon 416 and the second layer of intrinsic amorphous silicon 418 are in contact with a first layer of doped amorphous silicon 420 and a second layer of doped amorphous silicon 422, respectively. The first layer of doped amorphous silicon 420 is a p-type silicon layer. In some cases, the first layer of doped amorphous silicon 420 includes boron as a dopant. The first layer of doped amorphous silicon 420 is the sun-facing side of the photovoltaic device 400. The second layer of doped amorphous silicon 422 is an n-type silicon layer. In some cases, the second layer of doped amorphous silicon 422 includes phosphorous as a dopant. A thickness of the first layer of doped amorphous silicon 420 is in a range of 5 nm to 30 nm (e.g., 10 nm to 20 nm). A thickness of the second layer of doped amorphous silicon 422 is in a range of 5 nm to 30 nm (e.g., 10 nm to 20 nm).

The first metal oxide layer 404 is a transparent conductive metal oxide layer. A thickness of the first metal oxide layer 404 is in a range of 0.1 nm to 50 nm. The metal layer 406 includes silver. A thickness of the metal layer 406 is in a range of 6 nm to 40 nm (e.g., 10 nm to 30 nm). The second metal oxide layer 408 is a transparent conductive metal oxide layer. The first metal oxide layer 404 and the second metal oxide layer 408 may be the same or different. A thickness of the second metal oxide layer 408 is in a range of 10 nm to 50 nm. Examples of suitable metal oxides for the first and second metal oxide layers include aluminum zinc oxide, indium zinc oxide, indium tin oxide, tin oxide, zinc oxide, cerium oxide, gallium zinc oxide, hydrogenated indium oxide, and indium cerium oxide.

In some implementations, the first metal oxide layer 404 is omitted. For example, the metal layer 406 is disposed on the first surface 403 of the silicon substrate 402 and the second metal oxide layer 408 is disposed on the metal layer 406.

As depicted in FIG. 4, the photovoltaic device 400 includes a first metal oxide layer 424 on a second surface 405 of the silicon substrate 402. The second surface 405 of the silicon substrate 402 is opposite the first surface 403 of the silicon substrate 402. The first metal oxide layer 424 is a transparent conductive metal oxide layer. A thickness of the first metal oxide layer 424 is in a range of 25 nm to 200 nm. Examples of suitable metal oxides for the first metal oxide layer 424 include aluminum zinc oxide, indium zinc oxide, indium tin oxide, tin oxide, zinc oxide, cerium oxide, gallium zinc oxide, hydrogenated indium oxide, and indium cerium oxide. The first metal oxide layer 404, the second metal oxide layer 408, and the first metal oxide layer 424 may be the same or different.

The photovoltaic device 400 includes a metal electrode layer 426 on the first metal oxide layer 424. The metal electrode layer 426 includes silver or aluminum. A thickness of the metal electrode layer 426 is in a range of 100 nm to 300 nm (e.g., 150 nm to 200 nm). An outer surface of the photovoltaic device 400 includes a metal contact 428 and a metal contact 430. In one example, metal contact 428 and metal contact 430 is composed of silver.

In some embodiments, one or both surfaces of a silicon substrate of a photovoltaic device includes two or more metal layers, each disposed between two metal oxide layers. In other embodiments, only a single surface of a silicon substrate of a photovoltaic device includes a metal layer disposed between metal oxide layers. In still other embodiments, a first surface of a silicon substrate of a photovoltaic device includes a metal layer between metal oxide layers, and a second surface of the silicon substrate of the photovoltaic device includes a metal layer and a single metal oxide layer.

In some cases, a photovoltaic device includes a perovskite cell with a silicon photovoltaic device. For example, a perovskite cell can include an electrode layer, a hole conductor layer disposed on the electrode layer, a perovskite layer disposed on the hole conductor layer, an electron conductor layer disposed on the perovskite layer, metal oxide layer disposed on the electron conductor layer, and a glass layer disposed on the transparent conductive oxide layer. The transparent conductive oxide layer, the electron conductor layer, or a combination thereof can include an encapsulated metal layer.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of fabricating a device, the method comprising:
vacuum depositing a metal layer over a silicon substrate; and
vacuum depositing a metal oxide layer on the metal layer, thereby disposing the metal layer between a surface of the silicon substrate and the metal oxide layer.

2. The method of claim 1, wherein the metal layer comprises silver, aluminum, copper, gold, or a combination thereof.

3. The method of claim 1, wherein the silicon substrate comprises a layer of crystalline n-type silicon having a first surface and a second surface opposite the first surface.

4. The method of claim 3, wherein the first surface, the second surface, or both are textured.

5. The method of claim 3, wherein the first surface and the second surface are in contact with a first layer of intrinsic amorphous silicon and a second layer of intrinsic amorphous silicon, respectively.

6. The method of claim 5, wherein the first layer of intrinsic amorphous silicon and the second layer of intrinsic amorphous silicon are in contact with a first layer of doped amorphous silicon and a second layer of doped amorphous silicon, respectively.

7. The method of claim 1, wherein vacuum depositing the metal oxide layer comprises forming the metal oxide layer on the metal layer in a vacuum chamber using a radiofrequency or direct current discharge.

8. The method of claim 7, wherein the radiofrequency or direct current discharge comprises argon and oxygen gas.

9. The method of claim 7, wherein a pressure in the vacuum chamber is in a range of 1 mTorr to 25 mTorr.

10. The method of claim 1, wherein a thickness of the metal layer is in a range of 6 nm to 40 nm and a thickness of the metal oxide layer is in a range of 10 nm to 50 nm.

11. The method of claim 1, further comprising annealing the device in air at a temperature in a range of 200° C. to 280° C.

12. The method of claim 1, further comprising disposing an electrically conductive material on the metal oxide layer, thereby forming a metal contact on the metal oxide layer.

13. The method of claim 1, further comprising, before vacuum depositing the metal layer:
vacuum depositing an additional metal oxide layer on the silicon substrate, thereby disposing the metal layer between the metal oxide layer and the additional metal oxide layer.

14. The method of claim 13, wherein the metal layer is in direct contact with the metal oxide layer and the additional metal oxide layer.

15. The method of claim 1, further comprising:
vacuum depositing an additional metal oxide layer on an additional surface of the silicon substrate, wherein the additional surface of the silicon substrate is opposite the surface of the silicon substrate;
optionally vacuum depositing an additional metal layer on the additional metal oxide layer; and
optionally vacuum depositing a second additional metal oxide layer on the additional metal layer, thereby disposing the additional metal layer between the additional metal oxide layer and the second additional metal oxide layer.

16. The method of claim 15, wherein a thickness of the additional metal oxide layer is in a range of 25 nm to 200 nm, a thickness of the additional metal layer is in a range up to 200 nm, and a thickness of the second additional metal oxide layer is in a range up to 50 nm.

17. The method of claim 15, further comprising vacuum depositing a metal electrode layer on the second additional metal oxide layer to yield the device.

18. The method of claim 17, wherein a thickness of the metal electrode layer is in a range of 100 nm to 300 nm.

19. The method of claim 1, further comprising:
vacuum depositing an additional metal layer on the metal oxide layer; and
vacuum depositing an additional metal oxide layer on the additional metal layer.

20. A device fabricated by the method of claim 1.
